(19) United States
(12) Patent Application Publication
(10) Pub. No.: US 2023/0299144 A1
(43) Pub. Date: Sep. 21, 2023

(54) SILICON CARBIDE SEMICONDUCTOR DEVICE

(71) Applicant: FUJI ELECTRIC CO., LTD., Kawasaki-shi (JP)

(72) Inventor: Shinichiro MATSUNAGA, Matsumoto-city (JP)

(73) Assignee: FUJI ELECTRIC CO., LTD., Kawasaki-shi (JP)

(21) Appl. No.: 18/160,198

(22) Filed: Jan. 26, 2023

(30) Foreign Application Priority Data
Mar. 18, 2022 (JP) 2022-044575

(51) Int. Cl. H01L 29/10; H01L 29/16; H01L 29/78

(52) U.S. Cl. CPC H01L 29/1095; H01L 29/1608; H01L 29/7813

(57) ABSTRACT

A silicon carbide semiconductor device has a silicon carbide semiconductor substrate of a first conductivity type, a first semiconductor layer of the first conductivity type, a second semiconductor layer of a second conductivity type, first semiconductor regions of the first conductivity type, trenches, gate electrodes provided via a gate insulating film, second semiconductor regions of the second conductivity type underlying the trenches, third semiconductor regions of the second conductivity type between adjacent trenches, a first electrode, and a second electrode. The silicon carbide semiconductor device has an active region end portion, which is free of the first semiconductor regions, and in which the third semiconductor regions are apart from sidewalls of the trenches and are connected to the second semiconductor regions.

### CROSS REFERENCE TO RELATED APPLICATIONS

This application is based upon and claims the benefit of priority of the prior Japanese Patent Application No. 2022-044575, filed on Mar. 18, 2022, the entire contents of which are incorporated herein by reference.

### BACKGROUND OF THE INVENTION

### 1. Field of the Invention

Embodiments of the invention relate to a silicon carbide semiconductor device.

### 2. Description of the Related Art

Silicon carbide (SiC) is expected as a next generation semiconductor material to replace silicon (Si). Compared to a conventional semiconductor device element using silicon as a semiconductor material, a semiconductor device element using silicon carbide as a semiconductor material (hereinafter, silicon carbide semiconductor device) has various advantages such as enabling resistance of a device element in an ON state to be reduced to a few hundredths of that conventionally and application under higher temperature (at least 200 degrees C.) environments. These advantages are due to characteristics of the material itself in that a band gap of silicon carbide is about 3 times larger than that of silicon and dielectric breakdown field strength thereof is nearly an order of magnitude greater than that of silicon.

Up to now, Schottky barrier diodes (SBDs) and vertical metal oxide semiconductor field effect transistors (MOSFETs) having a trench gate structure or planar gate structure have become commercialized as silicon carbide semiconductor devices.

A planar gate structure is a MOS gate structure in which a MOS gate is provided in a flat plate-like shape on a front surface of a semiconductor substrate. A trench gate structure is a MOS gate structure in which a MOS gate is embedded in a trench formed in a semiconductor substrate (semiconductor chip), at a front surface thereof and a channel (inversion layer) is formed along a sidewall of the trench in a direction orthogonal to the front surface of the semiconductor substrate. Therefore, compared to the planar gate structure in which a channel is formed along the front surface of the semiconductor substrate, unit cell (constituent unit of device element) density per unit area may be increased and current density per unit area may be increased, which are advantageous in terms of cost.

A structure of a conventional silicon carbide semiconductor device is described taking a trench-type MOSFET as an example. FIG. 9 is a cross-sectional view depicting a structure of an active region of the conventional silicon carbide semiconductor device. The active region is a region in which a device element structure is formed and through which current flows during an ON state.

In a trench gate structure of a trench-type MOSFET 150, an n⁻-type silicon carbide epitaxial layer 102 is deposited on a front surface of an n⁺-type silicon carbide substrate 101. The n⁻-type silicon carbide epitaxial layer 102 has a first surface and a second surface opposite to each other, the second surface faces the n⁺-type silicon carbide substrate 101, and an n-type high-concentration region 105 is provided at the first surface. In the n-type high-concentration region 105, a first p⁺-type base region 103 is selectively provided so as to entirely underlie a bottom of a trench 116. Between the trench 116 and an adjacent trench 116, a second p⁺-type base region 104 is provided, configured by a lower second p⁺-type base region 104b of a same height as that of the first p⁺-type base region 103, and an upper second p⁺-type base region 104a provided at an upper side of the lower second p⁺-type base region 104b.

A MOS gate of the trench gate structure is configured by a p-type base layer 106, an n⁺-type source region 107, a p⁺-type contact region 108, the trench 116, a gate insulating film 109, and a gate electrode 110. An interlayer insulating film 111 is provided so as to cover the gate electrode 110 embedded in the trench 116. The p⁺-type contact region 108 may be omitted. A source electrode 112 is provided on the n⁺-type source region 107 and the p⁺-type contact region 108, via a barrier metal (not depicted). On a back surface of the n⁺-type silicon carbide substrate 101, a back electrode 113 constituting a drain electrode is provided.

In the trench-type MOSFET 150 configured as such, to prevent malfunction due to the trench-type MOSFET 150 being turned ON by a low voltage, an electron channel threshold is set to be as high as possible. Therefore, for example, the p-type base layer 106 is set to have a high impurity concentration, an implanted channel layer 114 that is ion-implanted with an impurity is provided in the p-type base layer 106, or a large flat band voltage is set, whereby the electron channel threshold is increased.

FIG. 10 is a cross-sectional view depicting a structure of an active region end portion of the conventional silicon carbide semiconductor device. Further, FIG. 11 is a top view of the structure of the conventional silicon carbide semiconductor device. FIG. 9 is a cross-sectional view along cutting line A-A′ in FIG. 11; FIG. 10 is a cross-sectional view along cutting line B-B′ in FIG. 11. Here, an active region end portion 141 is a portion between an edge termination region (not depicted) and an active region 140, in particular, the active region end portion 141 is a region free of the n⁺-type source region 107 and in which p-type regions (the second p⁺-type base region 104, the p-type base layer 106, the implanted channel layer 114) are provided. The edge termination region is a region that mitigates electric field of a substrate front side of a drift region and maintains a breakdown voltage.

As depicted in FIG. 10, in the active region end portion 141 of the conventional silicon carbide semiconductor device, the upper second p⁺-type base region 104a is in contact with a sidewall of the trench 116, and the lower second p⁺-type base region 104b is connected to the first p⁺-type base region 103. As a result, due to the active region end portion 141, configuration is such that potential does not increase.

Further, a semiconductor device is commonly known in which close to a trench sidewall, a third p-type region is provided a predetermined distance from a trench sidewall and apart from first and second p⁺-type regions, whereby a tradeoff between reducing ON resistance and suppressing decreases in gate threshold voltage may be improved (for example, refer to Japanese Laid-Open Patent Publication No. 2019-050352).

Further, a silicon carbide semiconductor device is commonly known in which a p⁺-type high-concentration region is provided at a side of a p-type base region, the side thereof further outward than is an active region; and a portion between the p⁺-type high-concentration region and an n⁺-type source region and a portion between the p⁺-type high-concentration region and an outermost trench are regarded as a p-type silicon carbide epitaxial layer and exposed at a semiconductor substrate front surface, whereby under high temperatures, current controllability by gate voltage control may be enhanced (for example, refer to Japanese Laid-Open Patent Publication No. 2020-004876).

### SUMMARY OF THE INVENTION

According to an embodiment of the invention, a silicon carbide semiconductor device includes: a silicon carbide semiconductor substrate of a first conductivity type, the silicon carbide semiconductor substrate having a first main surface and a second main surface that are opposite to each other; a first semiconductor layer of the first conductivity type, provided on the first main surface of the silicon carbide semiconductor substrate, the first semiconductor layer having an impurity concentration that is lower than an impurity concentration of the silicon carbide semiconductor substrate, the first semiconductor layer having a first surface and a second surface that are opposite to each other, the second surface of the first semiconductor layer facing the silicon carbide semiconductor substrate; a second semiconductor layer of a second conductivity type, provided on the first surface of the first semiconductor layer, the second semiconductor layer having a first surface and a second surface that are opposite to each other, the second surface of the second semiconductor layer facing the silicon carbide semiconductor substrate; a plurality of first semiconductor regions of the first conductivity type, selectively provided on the first surface of the second semiconductor layer; a plurality of trenches, penetrating respectively through the first semiconductor regions and through the second semiconductor layer and reaching the first semiconductor layer; a plurality of gate insulating films provided respectively in the trenches; a plurality of gate electrodes, provided respectively in the trenches, via the plurality of gate insulating films; a plurality of second semiconductor regions of the second conductivity type, selectively provided in the first semiconductor layer, each of the second semiconductor regions underlying a bottom of one of the trenches; a plurality of third semiconductor regions of the second conductivity type, selectively provided in the first semiconductor layer and the second semiconductor layer, each between adjacent two of the trenches, the third semiconductor regions being in contact with the second semiconductor layer; a first electrode that is in contact with the second semiconductor layer and the first semiconductor regions; and a second electrode provided on the second main surface of the silicon carbide semiconductor substrate. The silicon carbide semiconductor device has an active region end portion that is free of the first semiconductor regions. In the active region end portion, each of the third semiconductor regions is apart from a sidewall of each of the two trenches between which said each third semiconductor region is located and is connected to at least one of the second semiconductor regions.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view depicting a structure of an active region of a silicon carbide semiconductor device according to an embodiment.

FIG. 2A is a cross-sectional view depicting the structure of an active region end portion of the silicon carbide semiconductor device according to the embodiment.

FIG. 2B is a cross-sectional view depicting another structure of the active region end portion of the silicon carbide semiconductor device according to the embodiment.

FIG. 3 is a top view of the structure of the silicon carbide semiconductor device according to the embodiment.

FIG. 4 is a graph depicting potential.

FIG. 5 is a cross-sectional view depicting operation of an active region end portion of a conventional silicon carbide semiconductor device during an OFF state.

FIG. 6 is a plan view depicting operation of the active region end portion of the conventional silicon carbide semiconductor device during the OFF state.

FIG. 7 is a cross-sectional view depicting operation of the active region end portion of the silicon carbide semiconductor device according to the embodiment, during the OFF state.

FIG. 8 is a plan view depicting operation of the active region end portion of the silicon carbide semiconductor device according to the embodiment, during the OFF state.

FIG. 9 is a cross-sectional view depicting a structure of an active region of the conventional silicon carbide semiconductor device.

FIG. 10 is a cross-sectional view depicting the structure of the active region end portion of the conventional silicon carbide semiconductor device.

FIG. 11 is a top view of the structure of the conventional silicon carbide semiconductor device.

FIG. 12 is a cross-sectional view depicting hole accumulation of the active region of the conventional silicon carbide semiconductor device.

FIG. 13 is a cross-sectional view depicting hole accumulation of the active region of the conventional silicon carbide semiconductor device.

### DETAILED DESCRIPTION OF THE INVENTION

First, problems associated with the conventional techniques are discussed. Here, when the impurity concentration of the p-type base layer 106 or the implanted channel layer 114 is increased to, thereby, increase the gate threshold voltage, the ON resistance increases and therefore, the extent to which the impurity concentration may be increased is limited. Further, while a large negative bias of about −5V, −10V, or −15V is favorable to prevent malfunction, the conventional silicon carbide semiconductor device is designed to turn OFF by a gate voltage at which holes (positive holes) do not accumulate.

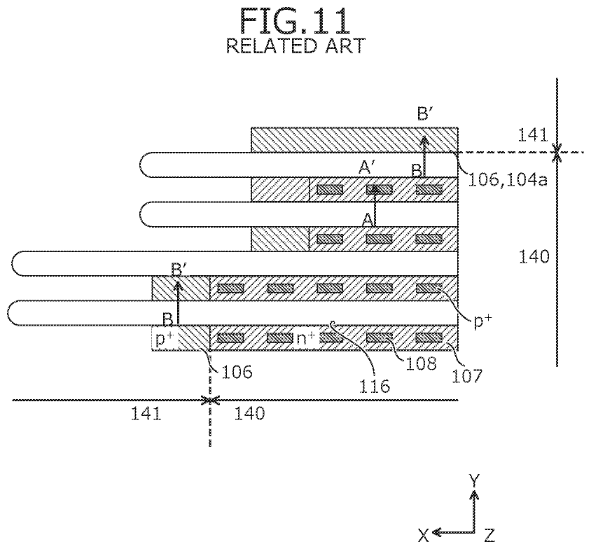

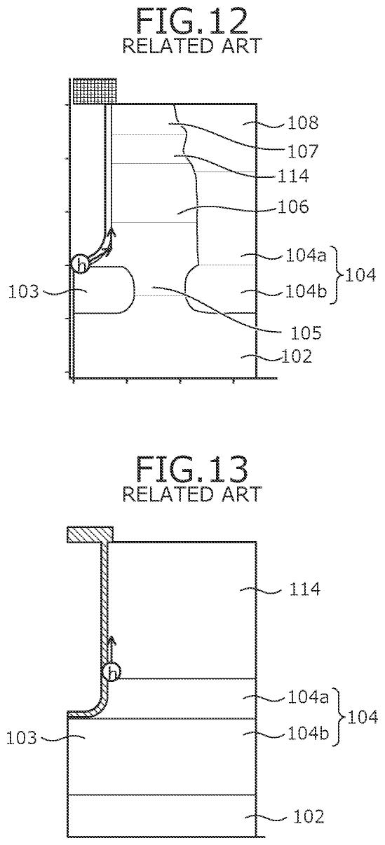

Nonetheless, depending on the SiC channel face orientation, trap type, and oxidation method of the gate insulating film 109, the voltage at which inherent holes begin to accumulate may be low. Here, FIG. 12 is a cross-sectional view depicting hole accumulation of the active region of the conventional silicon carbide semiconductor device. FIG. 13 is a cross-sectional view depicting hole accumulation of the active region of the conventional silicon carbide semiconductor device. In the conventional silicon carbide semiconductor device, even when negative gate bias is −3V or −2V, as depicted in FIGS. 12 and 13, holes accumulate at the trench sidewall interface and even in the ON state, the holes remain. As a result, a problem arises in that negative gate bias cannot be increased, which leads to malfunction during switching.

Embodiments of a silicon carbide semiconductor device according to the present invention are described in detail with reference to the accompanying drawings. In the present description and accompanying drawings, layers and regions prefixed with n or p mean that majority carriers are electrons or holes. Additionally, + or − appended to n or p means that the impurity concentration is higher or lower, respectively, than layers and regions without + or −. Cases where symbols such as n's and p's that include + or − are the same indicate that concentrations are close and therefore, the concentrations are not necessarily equal. In the description of the embodiments below and the accompanying drawings, main portions that are identical are given the same reference numerals and are not repeatedly described. Further, in the present description, when Miller indices are described, “-” means a bar added to an index immediately after the “-”, and a negative index is expressed by prefixing “−” to the index. Further, with consideration of variation in manufacturing, description indicating the same or equal may be within 5%.

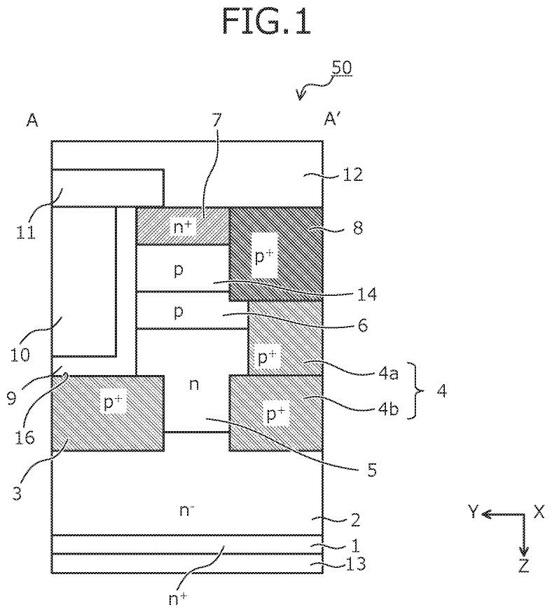

A semiconductor device according to the present invention contains a wide band gap semiconductor. In the embodiment, a silicon carbide semiconductor device fabricated (manufactured) using, for example, silicon carbide (SiC) as a wide band gap semiconductor is described taking a trench-type MOSFET 50 as an example. FIG. 1 is a cross-sectional view depicting a structure of an active region of the silicon carbide semiconductor device according to the embodiment.

As depicted in FIG. 1, in the silicon carbide semiconductor device according to the embodiment, an n⁻-type silicon carbide epitaxial layer (first semiconductor layer of a first conductivity type) 2 is deposited on a first main surface (front surface), for example, a (0001) plane (Si face), of an n⁺-type silicon carbide substrate (silicon carbide semiconductor substrate of the first conductivity type) 1.

The n⁺-type silicon carbide substrate 1 is a silicon carbide single crystal substrate. The n⁻-type silicon carbide epitaxial layer 2 has an impurity concentration that is lower than an impurity concentration of the n⁺-type silicon carbide substrate 1 and, for example, is a low-concentration n-type drift layer. The n⁻-type silicon carbide epitaxial layer 2 has a first surface and a second surface that are opposite to each other, the second surface faces the n⁺-type silicon carbide substrate 1, and at the first surface, an n-type high-concentration region 5 may be provided. The n-type high-concentration region 5 is a high-concentration n-type drift layer having an impurity concentration that is lower than the impurity concentration of the n⁺-type silicon carbide substrate 1 but higher than the impurity concentration of the n⁻-type silicon carbide epitaxial layer 2.

The n⁻-type silicon carbide epitaxial layer 2 has a first surface and a second surface that are opposite to each other, the second surface faces the n⁺-type silicon carbide substrate 1, and at the first surface, a p-type base layer (second semiconductor layer of a second conductivity type) 6 is provided. Hereinafter, the n⁺-type silicon carbide substrate 1, the n⁻-type silicon carbide epitaxial layer 2, the n-type high-concentration region 5, and the p-type base layer 6 combined are regarded as a silicon carbide semiconductor base (semiconductor substrate containing silicon carbide).

On a second main surface (back surface, i.e., back surface of the silicon carbide semiconductor base) of the n⁺-type silicon carbide substrate 1, a back electrode 13 constituting a drain electrode is provided. On a surface of the back electrode 13, a drain electrode pad (not depicted) is provided.

In the silicon carbide semiconductor base, in a side thereof having the first main surface thereof (side having the p-type base layer 6), a trench structure is formed. In particular, the p-type base layer 6 has a first surface and a second surface that are opposite to each other, the second surface faces the n⁺-type silicon carbide substrate 1, and from the first surface (the first main surface side of the silicon carbide semiconductor base), trenches 16 are provided, penetrating through the p-type base layer 6 and reaching the n-type high-concentration region 5 (in an instance in which the n-type high-concentration region 5 is omitted, the n⁻-type silicon carbide epitaxial layer 2, hereinafter, indicated as simply “(2)”). Along an inner wall of each of the trenches 16, a gate insulating film 9 is formed at a bottom and sidewalls of the trench 16, and a gate electrode 10 is formed on the gate insulating film 9 in the trench 16. The gate electrode 10 is insulated from the n-type high-concentration region 5 (2) and the p-type base layer 6 by the gate insulating film 9. A portion of the gate electrode 10 may protrude from a top (side facing a later-described source electrode 12) of the trench 16, in a direction to the source electrode 12.

In the n⁻-type silicon carbide epitaxial layer 2 and the n-type high-concentration region 5 (2), a p⁺-type base region (second semiconductor region of the second conductivity type) 3 is provided in contact with the bottom of the trench 16. The p⁺-type base region 3 is provided at a position facing the bottom of the trench 16 in a depth direction (direction from the source electrode 12 to the back electrode 13). The p⁺-type base region 3 has a width that is at least equal to a width of the trench 16. The bottom of the trench 16 may reach the p⁺-type base region 3 or may be positioned in the n-type high-concentration region 5 (2), between the p-type base layer 6 and the p⁺-type base region 3. Further, between each adjacent two of the trenches 16, a second p⁺-type base region (third semiconductor region of the second conductivity type) 4 is provided in the p-type base layer 6 and the n-type high-concentration region 5 (2). The second p⁺-type base region 4 is configured by a lower second p⁺-type base region 4b of a same height as that of the p⁺-type base region 3 and an upper second p⁺-type base region 4a provided on the surface of the lower second p⁺-type base region 4b. A width of the upper second p⁺-type base region 4a may be narrower than a width of the lower second p⁺-type base region 4b.

In the p-type base layer 6, in the first main surface side of the silicon carbide semiconductor base, an n⁺-type source region (first semiconductor region of the first conductivity type) 7 is selectively provided. Further, a p⁺-type contact region 8 may be selectively provided. Further, the n⁺-type source region 7 and the p⁺-type contact region 8 are in contact with each other. Further, in the p-type base layer 6, to suppress increases in saturation current and increases in leakage current due to a short-channel effect in an instance of high drain voltage, an implanted channel layer 14 of a p-type and having an impurity concentration that is higher than the impurity concentration of the p-type base layer 6 is provided close to a channel.

An interlayer insulating film 11 is provided on the entire surface of the first main surface side of the silicon carbide semiconductor base, so as to cover the gate electrodes 10 embedded in the trenches 16. The source electrode 12 is in contact with the n⁺-type source region 7 and the p-type base layer 6, via a contact hole opened in the interlayer insulating film 11. Further, in an instance in which the p⁺-type contact region 8 is provided, the source electrode 12 is in contact with the n⁺-type source region 7 and the p⁺-type contact region 8. The source electrode 12 is electrically insulated from the gate electrode 10 by the interlayer insulating film 11. On the source electrode 12, a source electrode pad (not depicted) is provided. Between the source electrode 12 and the interlayer insulating film 11, for example, a barrier metal (not depicted) that prevents diffusion of metal ions from the source electrode 12 to the gate electrode 10 may be provided.

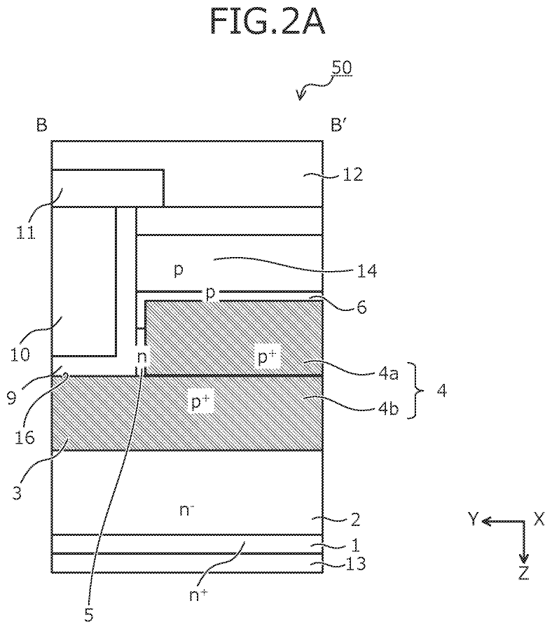

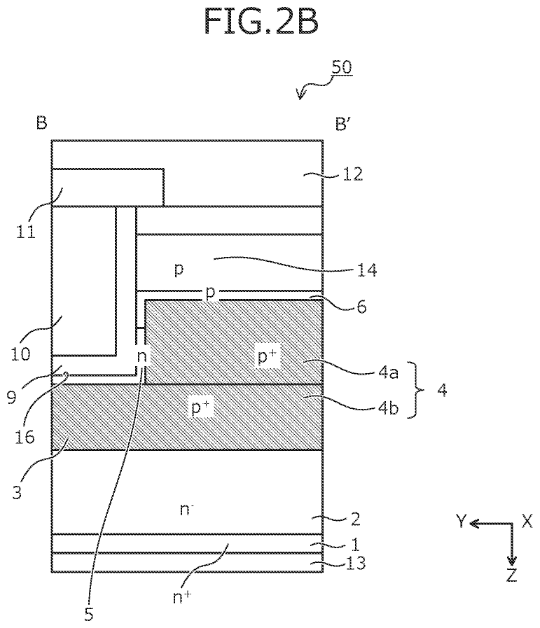

FIG. 2A is a cross-sectional view depicting the structure of an active region end portion of the silicon carbide semiconductor device according to the embodiment. FIG. 2B is a cross-sectional view depicting another structure of the active region end portion of the silicon carbide semiconductor device according to the embodiment. Further, FIG. 3 is a top view of the structure of the silicon carbide semiconductor device according to the embodiment. FIG. 1 is a cross-sectional view along cutting line A-A′ in FIG. 3, and FIGS. 2A and 2B are cross-sectional views along cutting line B-B′ in FIG. 3. Here, an active region end portion 41 is a portion between the edge termination region (not depicted) and an active region 40 and in particular, is a region free of the n⁺-type source region 7 and in which p-type regions (the second p⁺-type base region 4, the p-type base layer 6, and the implanted channel layer 14) are provided. The edge termination region is a region in which a JTE, a spatial modulation or guard ring, etc. is formed to mitigate electric field of a base front surface side of the drift region and maintain the breakdown voltage.

As depicted in FIG. 2A, in the silicon carbide semiconductor device of the embodiment, the upper second p⁺-type base region 4a is disposed apart from the sidewalls of the trench 16, in the active region end portion 41. Thus, the p-type base layer 6 and the n-type high-concentration region 5 (2) are provided between the upper second p⁺-type base region 4a and the trench 16. A distance between the upper second p⁺-type base region 4a and the trench 16 may be preferably at least 0.1 μm or more preferably may be at least 0.3 μm. Further, the lower second p⁺-type base region 4b is connected to the p⁺-type base region 3.

Further, as depicted in FIG. 2B, in the silicon carbide semiconductor device of the embodiment, the p⁺-type base region 3 may be further disposed apart from the bottom of the trench 16, in the active region end portion 41. Thus, the n-type high-concentration region 5 (2) is provided between the p⁺-type base region 3 and the bottom of the trench 16. A distance between the p⁺-type base region 3 and the bottom of the trench 16 may be preferably at least 0.1 μm or more preferably may be at least 0.3 μm. In FIG. 2B as well, the lower second p⁺-type base region 4b is connected to the p⁺-type base region 3. In this instance, in the active region 40 as well, the p⁺-type base region 3 may be disposed apart from the bottom of the trench 16.

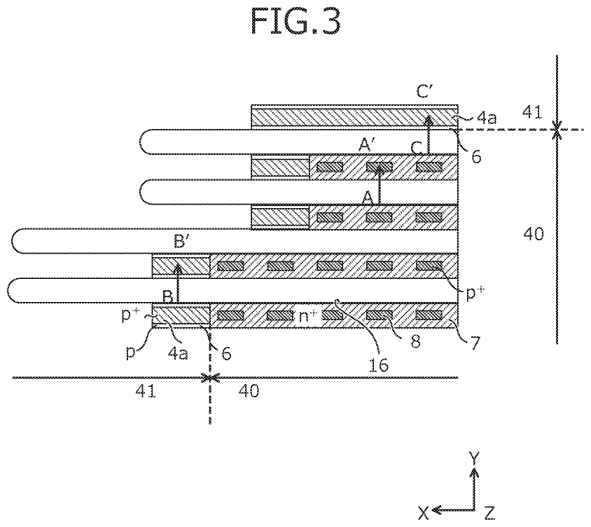

Here, FIG. 4 is a graph depicting potential. In FIG. 4, a horizontal axis indicates the distance from an interface (0.35 μm) of the gate insulating film 9 of the trench 16 to the implanted channel layer 14 or the upper second p⁺-type base region 4a side (within the SiC) in units of μm. A vertical axis indicates potential in units of V.

In FIG. 4, a curve indicated by triangles “Δ” and a dashed line indicates the potential of a p-type region having a high impurity concentration and a curve indicated by circles “∘” and a solid line indicates the potential of a p-type region having a low impurity concentration. Further, arrow A indicates a potential barrier that has to be crossed in order for holes to be induced from inside the SiC to the trench interface in the p-type region with a high impurity concentration, arrow B indicates a similar potential barrier in the p-type region of a low impurity concentration, and arrow C indicates the potential difference necessary when holes reach an oxide film interface of the p-type region of a low impurity concentration, via an oxide film interface of the p-type region of a high impurity concentration.

In order for holes that reach the trench interface of the p-type region of a high impurity concentration to move to the p-type region of a low impurity concentration, the potential barrier has to be crossed in a horizontal direction corresponding to arrow C. Nonetheless, the potential barrier (arrow C) in the horizontal direction is smaller than the original potential barrier (arrow B) for the substrate. Thus, in a p-type region of a low impurity concentration like the implanted channel layer 14, by a smaller bias than an expected negative gate bias, hole spreading, assisted by heat, begins in the horizontal direction from a p-type region of a high concentration.

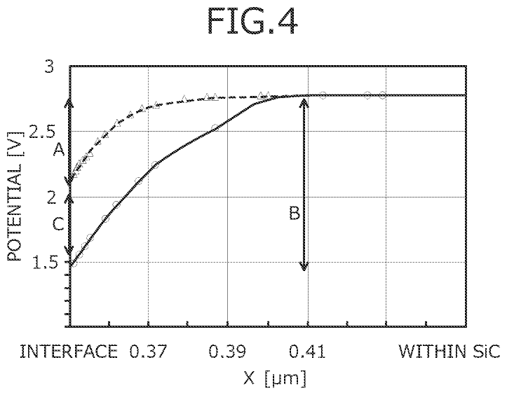

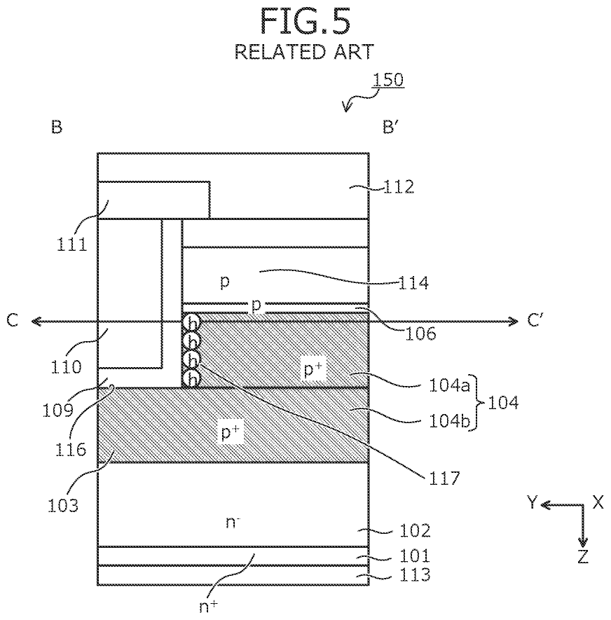

FIG. 5 is a cross-sectional view depicting operation of the active region end portion of the conventional silicon carbide semiconductor device during an OFF state. FIG. 6 is a plan view depicting operation of the active region end portion of the conventional silicon carbide semiconductor device during the OFF state. FIG. 6 is a cross-sectional view of a portion along cutting line C-C′ in FIG. 5. In a large portion of the active region 140, the impurity concentration of the implanted channel layer 114, which determines a threshold of the electron channel, is the highest concentration in the p-type base layer 106. In the active region end portion 141, formation of the electron channel is unnecessary and thus, the second p⁺-type base region 104 of a higher concentration is disposed.

A portion in which the electron channel threshold is high is a portion where a hole channel threshold is low and therefore, during the OFF state, when negative gate bias is applied, as depicted in FIG. 5, by a smaller gate negative voltage, holes 117 are induced at an interface of the second p⁺-type base region 104, that is, the interface between the second p⁺-type base region 104 and the gate insulating film 109 of the trench 116.

While the potential barrier is present in the second p⁺-type base region 104 of a high impurity concentration and the p-type base layer 106 of a low impurity concentration, as depicted in FIG. 4, a difference thereof is relatively small and therefore, the induced holes 117 of the active region end portion 141, as indicated by an arrow in FIG. 6, cross the potential barrier to the p-type base layer 106 of a low impurity concentration and spread via the trench interface. As a result, in the active region 140 as well, the holes 117 reach the interface of the gate insulating film 109 by a gate negative voltage smaller than the hole channel threshold of the p-type base layer 106 of a low impurity concentration.

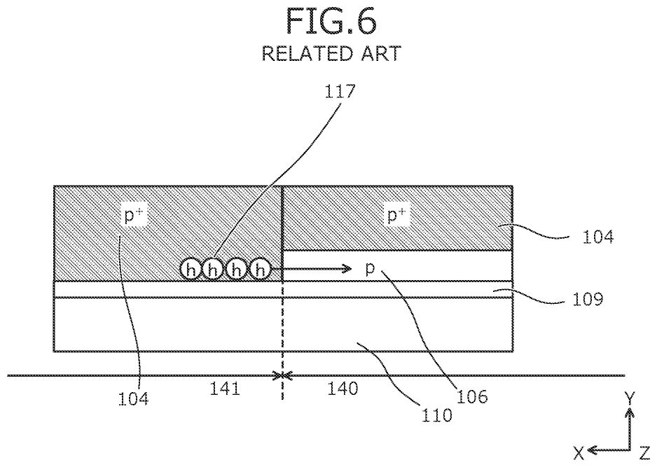

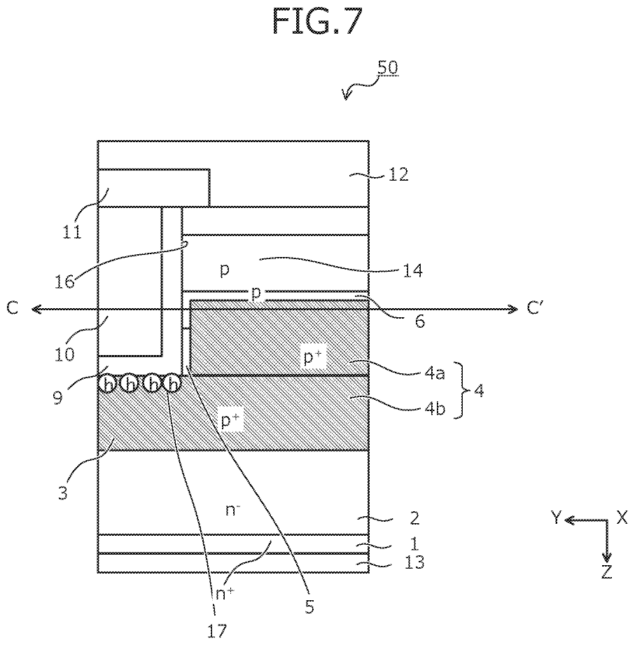

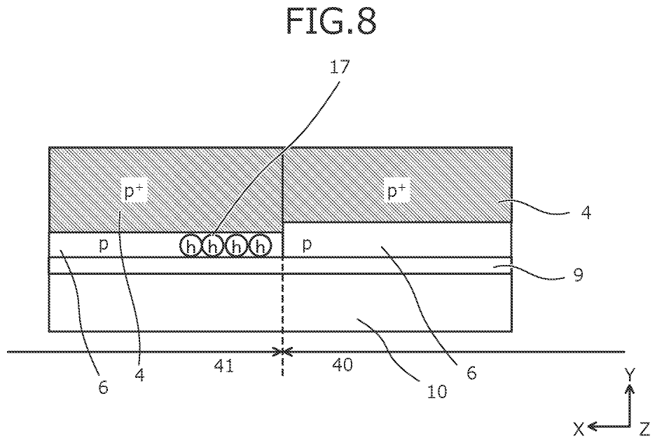

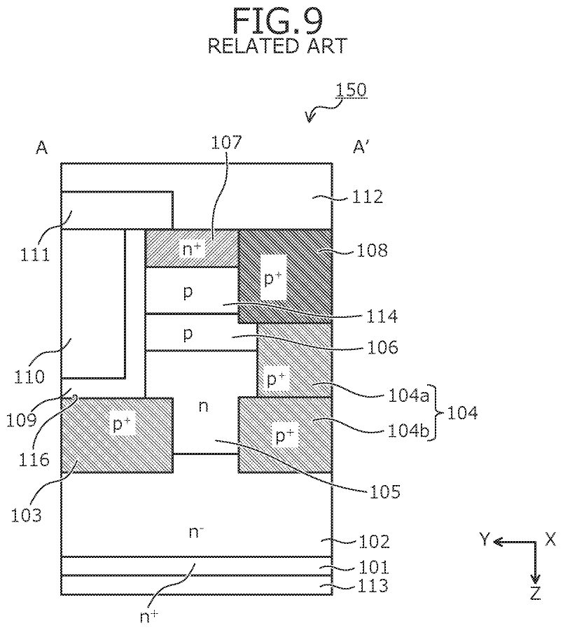

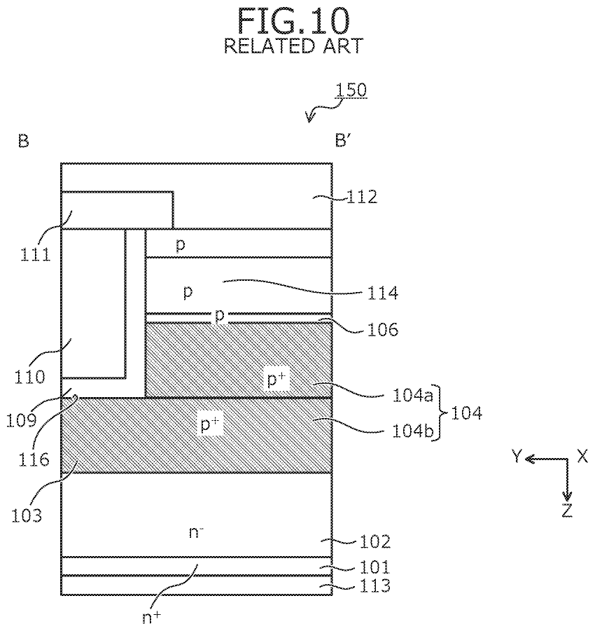

FIG. 7 is a cross-sectional view depicting operation of the active region end portion of the silicon carbide semiconductor device according to the embodiment, during the OFF state. FIG. 8 is a plan view depicting operation of the active region end portion of the silicon carbide semiconductor device according to the embodiment, during the OFF state. FIG. 8 is cross-sectional view along cutting line C-C′ in FIG. 7. In the silicon carbide semiconductor device according to the embodiment, in a large portion of the active region 40, the impurity concentration of the implanted channel layer 14, which determines the electron channel threshold, is the highest concentration in the p-type base layer 6. In the active region end portion 41, formation of the electron channel is unnecessary and thus, the second p⁺-type base region 4 of a higher concentration is disposed.

A portion having a high p-type impurity concentration is a portion where the hole channel threshold is low and therefore, during the OFF state, when a negative gate bias is applied, holes 17, as depicted in FIG. 7, are induced by a smaller gate negative voltage, at an interface of the lower second p⁺-type base region 4b, that is, the interface between the lower second p⁺-type base region 4b and the gate insulating film 9 of the trench 16.

In the embodiment, in the active region end portion 41, the second p⁺-type base region 4 of a high concentration is apart from the sidewall of trench 16. From the perspective of the holes of the trench interface of the n-type high-concentration region 5, the potential is even higher than that of the p-type region of a low impurity concentration and therefore, the induced holes 17 of the active region end portion 41 cannot cross the potential barrier and as depicted in FIG. 8, spreading thereof does not occur. As a result, in the active region 40, the holes 17 may be prevented from reaching the interface of the gate insulating film 9 by a gate negative voltage smaller than the hole channel threshold of the p-type base layer 6 of a low impurity concentration. Therefore, it becomes possible to use a higher negative gate voltage and malfunction during switching may be prevented.

Further, as depicted in FIG. 3, the trenches 16 are disposed in a striped pattern; the active region end portion 41 is present at ends (in a longitudinal direction (X-axis direction)) of the trenches 16 and at a portion of a trench 16 in a direction orthogonal to the longitudinal direction (Y-axis direction). At both locations, the trench 16 sidewalls and the upper second p⁺-type base region 4a are apart from each other. While not depicted in FIG. 3, in the active region end portion 41, the lower second p⁺-type base region 4b is provided at the entire surface including beneath the trench 16. The upper second p⁺-type base region 4a, as depicted in FIG. 3, in the active region end portion 41, may be provided at a portion of the sidewall of the trench 16 or the upper second p⁺-type base region 4a may be provided so as to surround the entire end of the trench 16.

As for the silicon carbide semiconductor device according to the embodiment, for example, when the second p⁺-type base region 4 is formed in the active region end portion 41, a layout of a mask for ion implantation is changed, the upper second p⁺-type base region 4a is formed to be apart from the sidewall of the trench 16, and the lower second p⁺-type base region 4b is formed to be connected to the p⁺-type base region 3, whereby the structure depicted in FIG. 2A may be formed. Furthermore, when the p⁺-type base region 3 is formed, ion implantation energy for the ion implantation is changed and the p⁺-type base region 3 is formed so as to be apart from the bottom of the trench 16, whereby the structure depicted in FIG. 2B may be formed. Further, another structure may be fabricated similarly to an instance in which, for example, a 1200V MOSFET is fabricated.

As described above, according to the embodiment, in the active region end portion, the second p⁺-type base region of a high concentration is apart from the trench sidewall. As a result, holes are not easily induced at the trench interfaces of the active region end portion. As a result, in the active region, the accumulation of holes at the interfaces of the gate insulating film, by a gate negative voltage that is smaller than the hole channel threshold of the p-type base layer may be prevented. Thus, it becomes possible to use a higher negative gate voltage and malfunction during switching may be prevented.

In the foregoing, the present invention may be variously modified within a range not departing from the spirit of the invention and in the embodiments described above, for example, dimensions, impurity concentration, etc. of parts may be variously set according to necessary specifications. Further, in the embodiment described above, while an instance in which silicon carbide is used as a wide band gap semiconductor is described as an example, a wide band gap semiconductor other than silicon carbide, for example, gallium nitride (GaN) or the like is applicable. Further, in the embodiments, while the first conductivity type is assumed to be an n-type and the second conductivity type is assumed to be a p-type, the present invention is similarly implemented when the first conductivity type is a p-type and the second conductivity type is an n-type.

According to the invention described above, in the active region end portion, the second p⁺-type base regions (third semiconductor regions of the second conductivity type) of a high concentration are apart from the trench sidewalls. As a result, the induced holes of the active region end portion do not spread in the p-type base layer (second semiconductor layer of the second conductivity type) of a low impurity concentration. As a result, in the active region, an accumulation of holes at the sidewall interfaces of the gate insulating film by a gate negative voltage that is smaller than the hole channel threshold of the p-type base layer may be prevented. Thus, it becomes possible to use a higher negative gate voltage and malfunction during switching may be prevented.

The silicon carbide semiconductor device according to the present invention achieves an effect in that the gate voltage by which holes begin to accumulate at the trench sidewall interfaces is changed to a high negative voltage, whereby it becomes possible to use a higher negative gate voltage and malfunction during switching may be prevented.

In this manner, the silicon carbide semiconductor device according to the present invention is useful for power semiconductor devices used in power converting equipment such as inverters, power source devices of various types of industrial machines, vehicle igniters, etc.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A silicon carbide semiconductor device, comprising:
a silicon carbide semiconductor substrate of a first conductivity type, the silicon carbide semiconductor substrate having a first main surface and a second main surface that are opposite to each other;
a first semiconductor layer of the first conductivity type, provided on the first main surface of the silicon carbide semiconductor substrate, the first semiconductor layer having an impurity concentration that is lower than an impurity concentration of the silicon carbide semiconductor substrate, the first semiconductor layer having a first surface and a second surface that are opposite to each other, the second surface of the first semiconductor layer facing the silicon carbide semiconductor substrate;
a second semiconductor layer of a second conductivity type, provided on the first surface of the first semiconductor layer, the second semiconductor layer having a first surface and a second surface that are opposite to each other, the second surface of the second semiconductor layer facing the silicon carbide semiconductor substrate;
a plurality of first semiconductor regions of the first conductivity type, selectively provided on the first surface of the second semiconductor layer;
a plurality of trenches, penetrating respectively through the first semiconductor regions and through the second semiconductor layer and reaching the first semiconductor layer;
a plurality of gate insulating films provided respectively in the trenches;
a plurality of gate electrodes, provided respectively in the trenches, via the plurality of gate insulating films;
a plurality of second semiconductor regions of the second conductivity type, selectively provided in the first semiconductor layer, each of the second semiconductor regions underlying a bottom of one of the trenches;
a plurality of third semiconductor regions of the second conductivity type, selectively provided in the first semiconductor layer and the second semiconductor layer, each between adjacent two of the trenches, the third semiconductor regions being in contact with the second semiconductor layer;
a first electrode that is in contact with the second semiconductor layer and the first semiconductor regions; and
a second electrode provided on the second main surface of the silicon carbide semiconductor substrate, wherein
the silicon carbide semiconductor device has an active region end portion that is free of the first semiconductor regions, and
in the active region end portion, each of the third semiconductor regions
is apart from a sidewall of each of the two trenches between which said each third semiconductor region is located, and
is connected to at least one of the second semiconductor regions.

2. The silicon carbide semiconductor device according to claim 1, wherein
in the active region end portion, each of the second semiconductor regions is apart from the bottom of the trench that said each second semiconductor region underlies.

3. The silicon carbide semiconductor device according to claim 1, wherein
in the active region end portion, said each third semiconductor region and said sidewall of each of the two trenches are separated from each other by the first semiconductor layer and the second semiconductor layer.

4. The silicon carbide semiconductor device according to claim 1, wherein
the trenches are disposed in a striped pattern in a top view of the silicon carbide semiconductor device, and
the active region end portion is an end portion of the silicon carbide semiconductor device in a longitudinal direction of the trenches.
